(19) United States
(12) Patent Application Publication
(10) Pub. No.: US 2013/0098428 A1
(43) Pub. Date: Apr. 25, 2013

(54) SUNLIGHT COMPLEX MODULES AND APPARATUSES FOR USING SOLAR ENERGY

(71) Applicants: Ho-Gyeong YUN, Seoul (KR); Seok-Hwan Moon, Daejeon (KR); Yong-Duck Chung, Daejeon (KR)

(72) Inventors: Ho-Gyeong YUN, Seoul (KR); Seok-Hwan Moon, Daejeon (KR); Yong-Duck Chung, Daejeon (KR)

(73) Assignee: ELECTRONICS AND TELECOMMUNICATIONS RESEARCH INSTITUTE, Daejeon (KR)

(21) Appl. No.: 13/569,507

(22) Filed: Aug. 8, 2012

(30) Foreign Application Priority Data
Oct. 21, 2011 (KR) 10-2011-0107877
Dec. 21, 2011 (KR) 10-2011-0139200

(51) Int. Cl. H01L 31/058

(52) U.S. Cl. 136/248

(57) ABSTRACT

Provided is a sunlight complex module, which includes a photovoltaic conversion part that generates electrical energy from sunlight,

a heat collector board attached to a bottom of the photovoltaic conversion part to collect heat from a portion of the sunlight, which has a wavelength to pass through the photovoltaic conversion part, a heat pipe attached to the heat collector board, and transferring thermal energy collected in the heat collector board, to an outside thereof,

and a mold sealed to maintain a vacuum therein. The photovoltaic conversion part, the heat collector board, and the heat pipe are accommodated in the mold.

### CROSS-REFERENCE TO RELATED APPLICATIONS

This U.S. non-provisional patent application claims priority under 35 U.S.C. §119 of Korean Patent Application Nos. 10-2011-0107877, filed on Oct. 21, 2011, and 10-2011-0139200, filed on Dec. 21, 2011, the entire contents of which are hereby incorporated by reference.

### BACKGROUND OF THE INVENTION

The present invention disclosed herein relates to a system for using solar energy, and more particularly, to a sunlight complex module and an apparatus for using solar energy, which simultaneously performs an electricity generating process and a heat collecting process, to thereby improve solar energy usage efficiency.

Power generating methods for using solar energy include: a solar photovoltaic power generating method in which sunlight is converted into electrical energy; a solar heat power generating method in which solar heat is converted into electrical energy; and a solar heat collection power generating method in which solar heat is collected to heat air or water. However, such solar power generating methods have low usage efficiency, and thus have low economic performance. Thus, the development of various methods for using solar energy is needed.

For example, a complex apparatus for using solar energy individually performs a solar photovoltaic power generating process and a solar heat power generating process. Thus, to simultaneously use electricity and heat, spatially isolated two facilities are used together.

A photovoltaic thermal hybrid solar (PVT) system, which simultaneously uses sunlight and solar heat, is a complex system for simultaneously performing a photovoltaic conversion process and a thermal energy generating process, thereby simultaneously generating electricity and heat. Such a PVT system includes a solar cell module, a heat collector board for cooling and collecting thermal energy, and a storage for recovering and storing heat. Further, the PVT system may include a photovoltaic sun tracking device and an inverter for AC/DC conversion.

Flat type PVT systems are widely developed, which may be classified into air type PVT systems and liquid type PVT systems according to cooling and heat collecting processes at the rear surface of a solar cell. The air type PVT systems can introduce collected thermal energy into a building to heat air therein. The liquid type PVT systems can heat water to a low or medium temperature. The liquid type PVT systems have a specific volume smaller than that of the air type PVT systems, and thus have high energy density so as to efficiently collect heat. All of the liquid type PVT systems and the air type PVT systems include a structure for heating a fluid passing through a chamber installed on the rear surface of a solar cell.

However, such a PVT system includes a thermoelectric element and a heat absorbing panel on the rear surface of a panel on which a solar cell is placed, and thus, heat absorbed by the PVT system is insufficient to simultaneously perform a solar photovoltaic power generation process and a solar heat power generation process. Furthermore, when a PVT system has a water-cooled structure, the volume thereof is increased.

### SUMMARY OF THE INVENTION

The present invention provides a sunlight complex module using solar energy to simultaneously perform an electricity generating process and a heat collecting process, and a solar energy usage apparatus including the sunlight complex module.

The present invention also provides a sunlight complex module for improving solar energy usage efficiency, and a solar energy usage method using the sunlight complex module.

Embodiments of the present invention provide sunlight complex modules including: a photovoltaic conversion part that generates electrical energy from sunlight; a heat collector board attached to a bottom of the photovoltaic conversion part to collect heat from a portion of the sunlight, which has a wavelength to pass through the photovoltaic conversion part; a heat pipe attached to the heat collector board, and transferring thermal energy collected in the heat collector board, to an outside thereof; and a mold sealed to maintain a vacuum therein, wherein the photovoltaic conversion part, the heat collector board, and the heat pipe are accommodated in the mold.

In some embodiments, the heat pipe may transfer the thermal energy to the outside thereof through a phase transition between gas and liquid.

In other embodiments, an inner wall of the heat pipe may have one of a wick structure and a groove structure.

In still other embodiments, the mold may have one of a circular cross section, an oval cross section, a tetragonal cross section, and a semi-circular cross section.

In even other embodiments, the photovoltaic conversion part may include at least one of a dye-sensitized solar cell, a copper-indium-selenium (CIS) solar cell, a cadmium-telluride (CdTe) solar cell, and an organic solar cell.

In yet other embodiments, the photovoltaic conversion part may include a plurality of photovoltaic conversion devices that are disposed on the heat collector board.

In further embodiments, the sunlight complex modules may further include an adhesion part disposed between the photovoltaic conversion part and the heat collector board to attach the photovoltaic conversion part to an upper portion of the heat collector board.

In still further embodiments, a portion of the heat pipe protruding from the mold may be sealed to maintain the vacuum in the mold.

In other embodiments of the present invention, apparatuses for using solar energy include: a plurality of sunlight complex modules; a passage through which a fluid medium transfers thermal energy transferred from the sunlight complex modules; a heat storage storing the thermal energy transferred through the passage; and a collector that stores electrical energy transferred from the sunlight complex modules, wherein each of the sunlight complex modules includes: a photovoltaic conversion part that generates electrical energy from sunlight; a heat collector board attached to a bottom of the photovoltaic conversion part to collect heat from a portion of the sunlight, which has a wavelength to pass through the photovoltaic conversion part; a heat pipe attached to the heat collector board, and transferring thermal energy collected in the heat collector board, to an outside thereof; and a mold sealed to maintain a vacuum therein, wherein the photovoltaic conversion part, the heat collector board, and the heat pipe are accommodated in the mold.

In some embodiments, the fluid medium of the passage may receive thermal energy from the heat pipe.

In other embodiments, the apparatuses may further include a conductive wire connected to the heat collector board to receive the electrical energy.

In still other embodiments, the collector may collect the electrical energy through the conductive wire.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a collection of views illustrating a sunlight complex module including a photovoltaic conversion part on a heat collector board according to an embodiment of the present invention;

FIG. 2 is a cross-sectional view illustrating a sunlight complex module in which a photovoltaic conversion part and a heat collector board are attached to each other, according to another embodiment of the present invention;

FIG. 3 is a collection of views illustrating a sunlight complex module including a photovoltaic conversion part that is partially formed on a heat collector board, according to another embodiment of the present invention;

FIG. 4 is a cross-sectional view illustrating a sunlight complex module in which a photovoltaic conversion part is partially attached to a heat collector board, according to another embodiment of the present invention;

FIG. 5 is a collection of views illustrating a sunlight complex module in which a photovoltaic conversion part and a heat collector board are divided by a heat pipe, according to another embodiment of the present invention;

FIG. 6 is a collection of views illustrating a sunlight complex module in which a heat collector board is divided by a heat pipe, according to another embodiment of the present invention;

FIG. 7 is a cross-sectional view illustrating a sunlight complex module including a mold having an oval structure, according to another embodiment of the present invention;

FIG. 8 is a cross-sectional view illustrating a sunlight complex module including a mold having a tetragonal structure, according to another embodiment of the present invention;

FIG. 9 is a schematic view illustrating an apparatus for using solar energy, which includes an array of sunlight complex modules, according to another embodiment of the present invention;

FIG. 10 is a schematic view illustrating an apparatus for using solar energy, a portion of which includes sunlight complex modules, according to another embodiment of the present invention; and

FIG. 11 is a schematic view illustrating an apparatus for using solar energy, a portion of which includes a sunlight complex module set, according to another embodiment of the present invention.

### DETAILED DESCRIPTION OF PREFERRED EMBODIMENTS

Preferred embodiments of the present invention will be described below in more detail with reference to the accompanying drawings. Moreover, detailed descriptions related to well-known functions or configurations will be ruled out in order not to unnecessarily obscure subject matters of the present invention.

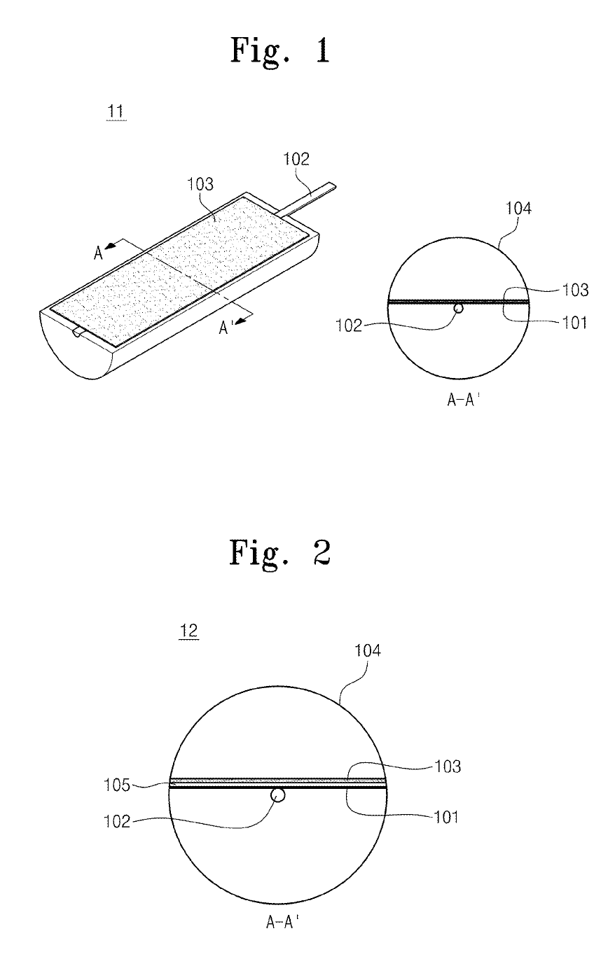

FIG. 1 is a collection of views illustrating a sunlight complex module including a photovoltaic conversion part on a heat collector board according to an embodiment of the present invention.

Referring to FIG. 1, a sunlight complex module 11 according to the current embodiment includes a heat collector board 101, a heat pipe 102, a photovoltaic conversion part 103, and a mold 104.

The heat collector board 101 absorbs thermal energy from sunlight, that is, solar heat. The heat collector board 101 may be formed of a metal having high coefficient thermal conductivity, such as copper or aluminum, or a nonmetal. The heat collector board 101 transfers solar heat (that is, solar energy) absorbed from sunlight, to the heat pipe 102. The heat collector board 101 may be referred to as an absorbing board.

The heat pipe 102 includes a working fluid therein to cause a phase transition between gas and liquid. A vacuum is maintained in the heat pipe 102 that includes a heat transfer mechanism using latent heat. Thus, the heat pipe 102 transfers heat from a high temperature region to a low temperature region. Particularly, solar heat transferred to the heat pipe 102 heats the working fluid in an evaporating part of the heat pipe 102 so as to generate vapor, and the generated vapor, which absorbs latent heat, is transferred to a condensing part of the heat pipe 102 having a relatively low temperature, and the latent heat is diffused. Such heat energy diffused by the heat pipe 102 may be stored in a heat storage, e.g., by a moving fluid. When the latent heat is diffused, the vapor is condensed to liquid that returns to the evaporating part.

For example, an inner wall of the heat pipe 102 may have a capillary groove structure or one of various wick structures for generating capillary force. To this end, a bunch of wires, a woven wire net, a sintered body, a screen net, or a fiber body may be used. A portion of the heat pipe 102 may protrude from the heat collector board 101 to transfer thermal energy through a vapor/liquid phase transition. Thus, the portion of the heat pipe 102 for transferring thermal energy to the outside of the sunlight complex module 11 may function as the condensing part, and the evaporating part may be disposed at a horizontal side of the condensing part. For example, the evaporating part may be disposed lower than the condensing part to move a fluid condensed within the heat pipe 102.

The photovoltaic conversion part 103 is disposed above the heat collector board 101. The photovoltaic conversion part 103 converts sunlight into electrical energy such as electric current. The photovoltaic conversion part 103 may output electrical energy to, e.g., a storage battery (not shown). The photovoltaic conversion part 103 may cover the heat collector board 101, and be referred to as a solar cell.

The photovoltaic conversion part 103 may be a thin film solar cell such as a copper-indium-selenium (Cu—In—Se; CIS) solar cell. The CIS solar cell includes a five-membered compound with a portion of indium (In) replaced with gallium (Ga) and a portion of selenium (Se) replaced with sulfur (S). The CIS solar cell can adjust a band gap (an energy band gap), that is, a light absorption coefficient, and thus, can provide an optimal band gap for separating photovoltaic conversion from heat collection.

The photovoltaic conversion part 103 may be a dye-sensitized solar cell (DSC). The dye-sensitized solar cell may transmit a portion of sunlight. To this end, a transmitted amount or wavelength of light may be adjusted according to a combination of a dye and an oxide semiconductor. Particularly, a portion of sunlight having a wavelength longer than a visible light band is not used in the photovoltaic conversion part 103, and is transmitted thereby.

The photovoltaic conversion part 103 may be a thin film solar cell such as a thin film silicon solar cell including an amorphous silicon thin film, a cadmium telluride (CdTe) solar cell, or an organic solar cell.

A vacuum is maintained in the mold 104 that is formed of a transparent material to transmit sunlight. Referring to the cross-sectional view of FIG. 1 taken along line A-A′ of the perspective view thereof, the mold 104 may have a circular cross section. The mold 104 may accommodate the heat collector board 101, the heat pipe 102, and the photovoltaic conversion part 103. The interface between the mold 104 and the heat pipe 102 is sealed to maintain the vacuum in the mold 104.

A portion of sunlight undergoes a photovoltaic conversion within the photovoltaic conversion part 103, and the rest of the sunlight is transmitted to the heat collector board 101 by the photovoltaic conversion part 103.

A conductive wire (not shown) may be connected to a surface of the photovoltaic conversion part 103 contacting the heat pipe 102, or another surface thereof, and provide electricity from the photovoltaic conversion part 103 to an external collector or a storage battery. The conductive wire may be formed of a material having high electrical conductivity.

The interface between the mold 104 and the conductive wire connected to the photovoltaic conversion part 103 is sealed to maintain the vacuum in the mold 104.

As such, according to the embodiment of the present invention, photovoltaic conversion and heat collection may be simultaneously carried out by using a heat pipe, a heat collector board, and a photovoltaic conversion part in a vacuous mold that efficiently transmits sunlight. To this end, the photovoltaic conversion part is disposed on the heat collector board. Thus, sunlight incident to a sunlight complex module is converted into electricity by the photovoltaic conversion part, and a portion of sunlight, which has a wavelength to pass through the photovoltaic conversion part, is used to collect heat, thereby maximizing energy usage efficiency.

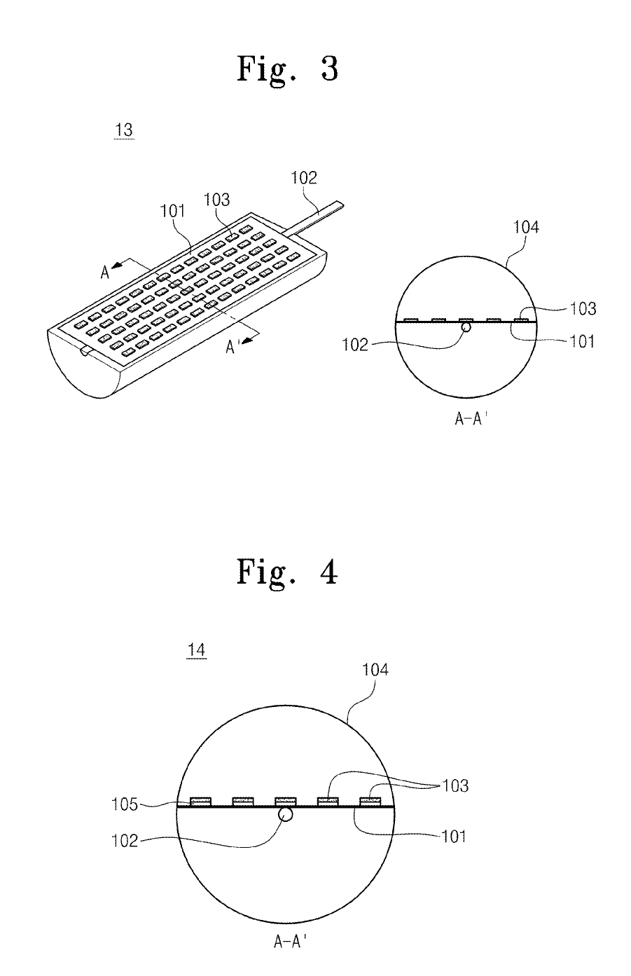

FIG. 2 is a cross-sectional view illustrating a sunlight complex module in which a photovoltaic conversion part and a heat collector board are attached to each other, according to another embodiment of the present invention.

Referring to FIG. 2, a sunlight complex module 12 according to the current embodiment includes a heat collector board 101, a heat pipe 102, a photovoltaic conversion part 103, a mold 104, and an adhesion part 105. The sunlight complex module 12 is similar to the sunlight complex module 11 of FIG. 1 except that the heat collector board 101 is attached to the photovoltaic conversion part 103 with the adhesion part 105 therebetween. Thus, the configuration of the sunlight complex module 12 except for the adhesion part 105 is referred to in the detailed description of the sunlight complex module 11 of FIG. 1.

The adhesion part 105 is disposed between the heat collector board 101 and the photovoltaic conversion part 103, and connects the heat collector board 101 and the photovoltaic conversion part 103 to each other. The adhesion part 105 may be formed of an adhesion material to transfer solar heat transmitted by the photovoltaic conversion part 103.

FIG. 3 is a collection of views illustrating a sunlight complex module including a photovoltaic conversion part that is partially formed on a heat collector board, according to another embodiment of the present invention.

Referring to FIG. 3, a sunlight complex module 13 according to the current embodiment includes a heat collector board 101, a heat pipe 102, a photovoltaic conversion part 103, and a mold 104. The photovoltaic conversion part 103 may include a plurality of photovoltaic conversion devices.

The photovoltaic conversion devices are disposed in respective positions on the heat collector board 101. The sunlight complex module 13 is similar to the sunlight complex module 11 of FIG. 1 except that the photovoltaic conversion devices of the photovoltaic conversion part 103 are disposed on the heat collector board 101. Thus, the configuration of the sunlight complex module 13 except for the photovoltaic conversion part 103 is referred to in the detailed description of the sunlight complex module 11 of FIG. 1.

As a result, the photovoltaic conversion part 103 is partially formed on the heat collector board 101. The photovoltaic conversion devices have tetragonal shapes, but are not limited thereto.

Referring to the cross-sectional view of FIG. 3 taken along line A-A′ of the perspective view thereof, the mold 104 may have a circular cross section. The photovoltaic conversion devices are partially formed on the heat collector board 101.

FIG. 4 is a cross-sectional view illustrating a sunlight complex module in which a photovoltaic conversion part is partially attached to a heat collector board, according to another embodiment of the present invention.

Referring to FIG. 4, a sunlight complex module 14 according to the current embodiment includes a heat collector board 101, a heat pipe 102, a photovoltaic conversion part 103, a mold 104, and an adhesion part 105. The sunlight complex module 14 is similar to the sunlight complex module 13 of FIG. 3 except that the heat collector board 101 is attached to the photovoltaic conversion part 103 with the adhesion part 105 therebetween.

The adhesion part 105 is disposed between the heat collector board 101 and the photovoltaic conversion part 103, and connects the heat collector board 101 and the photovoltaic conversion part 103 to each other. The adhesion part 105 may be formed of an adhesion material to transfer solar heat transmitted by the photovoltaic conversion part 103. Thus, the adhesion part 105 has the same size as that of the photovoltaic conversion part 103, and is disposed on the bottom of the photovoltaic conversion part 103 to attach the photovoltaic conversion part 103 to the heat collector board 101.

The sunlight complex module 14 is similar to the sunlight complex module 13 of FIG. 3 except that the heat collector board 101 is attached to the photovoltaic conversion part 103 with the adhesion part 105 therebetween. Thus, a description of the other configuration of the sunlight complex module 14 will be omitted.

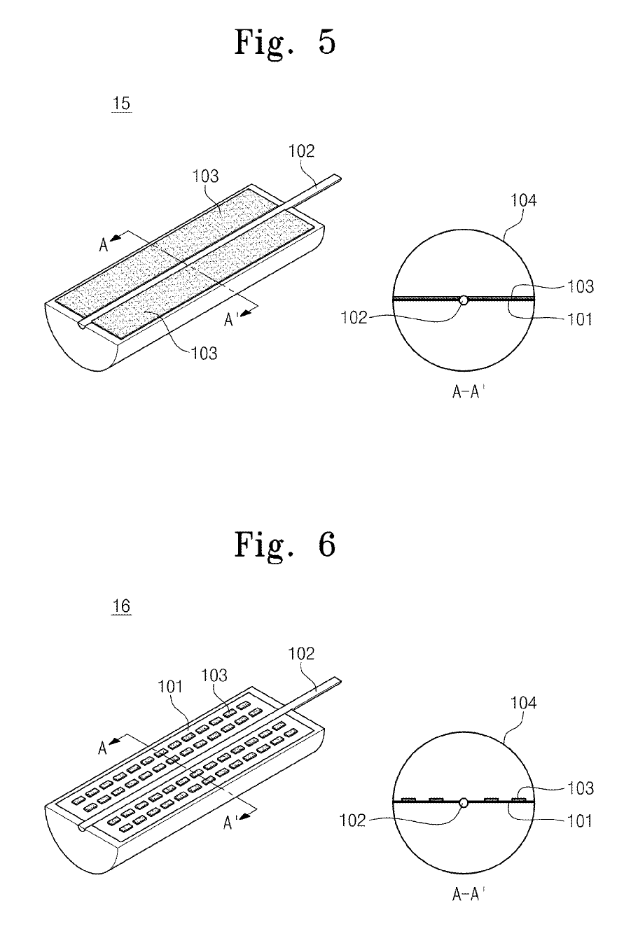

FIG. 5 is a collection of views illustrating a sunlight complex module in which a photovoltaic conversion part and a heat collector board are divided by a heat pipe, according to another embodiment of the present invention.

Referring to FIG. 5, a sunlight complex module 15 according to the current embodiment includes a heat collector board 101, a heat pipe 102, a photovoltaic conversion part 103, and a mold 104. The heat collector board 101 is divided by the heat pipe 102. Thus, the heat pipe 102 is not disposed on the bottom of the heat collector board 101, and may be disposed on a side portion thereof. That is, division parts of the heat collector board 101 may be connected to the heat pipe 102. Division parts of the photovoltaic conversion part 103 are coupled to the division parts of the heat collector board 101 divided by the heat pipe 102, respectively. The number of the division parts of the heat collector board 101 and the number of the division parts of the photovoltaic conversion part 103 are two, but are not limited thereto.

Referring to the cross-sectional view of FIG. 5 taken along line A-A′ of the perspective view thereof, the mold 104 may have a circular cross section. The mold 104 may accommodate the heat collector board 101, the heat pipe 102, and the photovoltaic conversion part 103. The heat pipe 102 divides the heat collector board 101 and the photovoltaic conversion part 103. The interface between the mold 104 and the heat pipe 102 is sealed to maintain a vacuum in the mold 104.

The sunlight complex module 15 is similar to the sunlight complex module 11 of FIG. 1 except that the heat pipe 102 divides the heat collector board 101 and the photovoltaic conversion part 103. Thus, the configuration of the sunlight complex module 15 is referred to in the detailed description of the sunlight complex module 11 of FIG. 1.

FIG. 6 is a collection of views illustrating a sunlight complex module in which a heat collector board is divided by a heat pipe, according to another embodiment of the present invention.

Referring to FIG. 6, a sunlight complex module 16 according to the current embodiment includes a heat collector board 101, a heat pipe 102, a photovoltaic conversion part 103, and a mold 104. The heat collector board 101 is divided by the heat pipe 102. Thus, the heat pipe 102 is not disposed on the bottom of the heat collector board 101, and may be disposed on a side portion thereof. That is, division parts of the heat collector board 101 may be connected to the heat pipe 102. Division parts of the photovoltaic conversion part 103 are coupled to the division parts of the heat collector board 101 divided by the heat pipe 102. The number of the division parts of the heat collector board 101 is two, but is not limited thereto.

Referring to the cross-sectional view of FIG. 6 taken along line A-A′ of the perspective view thereof, the mold 104 may have a circular cross section. The mold 104 may accommodate the heat collector board 101, the heat pipe 102, and the photovoltaic conversion part 103. The heat pipe 102 divides the heat collector board 101. The interface between the mold 104 and the heat pipe 102 is sealed to maintain a vacuum in the mold 104.

The sunlight complex module 16 is similar to the sunlight complex module 13 of FIG. 3 except that the heat pipe 102 divides the heat collector board 101. Thus, the configuration of the sunlight complex module 16 is referred to in the detailed description of the sunlight complex module 13 of FIG. 3.

Furthermore, the sunlight complex modules 15 and 16 of FIGS. 5 and 6 may include an adhesion part 105 between the heat collector board 101 and the photovoltaic conversion part 103.

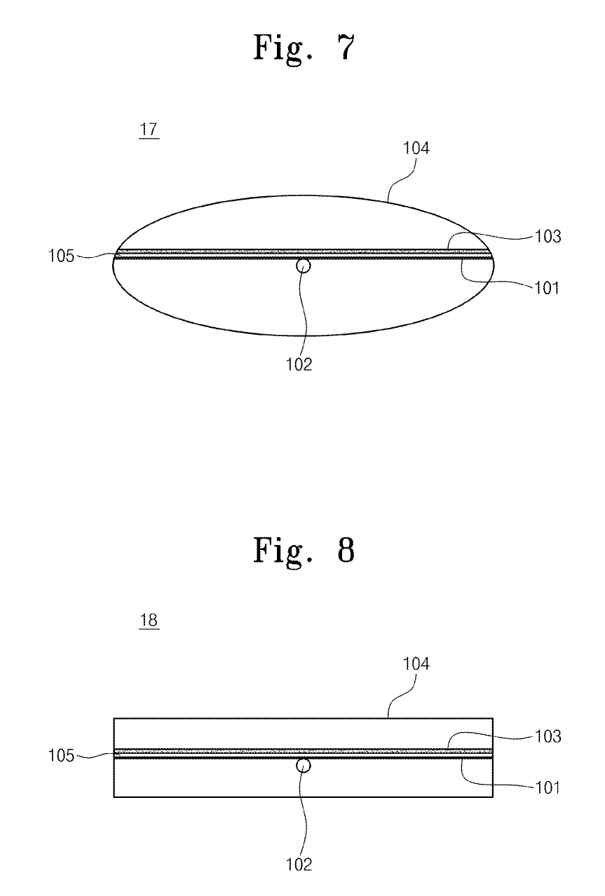

FIG. 7 is a cross-sectional view illustrating a sunlight complex module including a mold having an oval structure, according to another embodiment of the present invention.

Referring to FIG. 7, a sunlight complex module 17 according to the current embodiment includes a mold 104 that may accommodate a heat collector board 101, a heat pipe 102, a photovoltaic conversion part 103, and an adhesion part 105. An inner structure of the mold 104 is similar to that of the sunlight complex module 12 of FIG. 2.

The mold 104 has an oval (track-shaped) cross section that is different from the circular cross section of the sunlight complex module 12. Thus, the mold 104 may have an oval column shape.

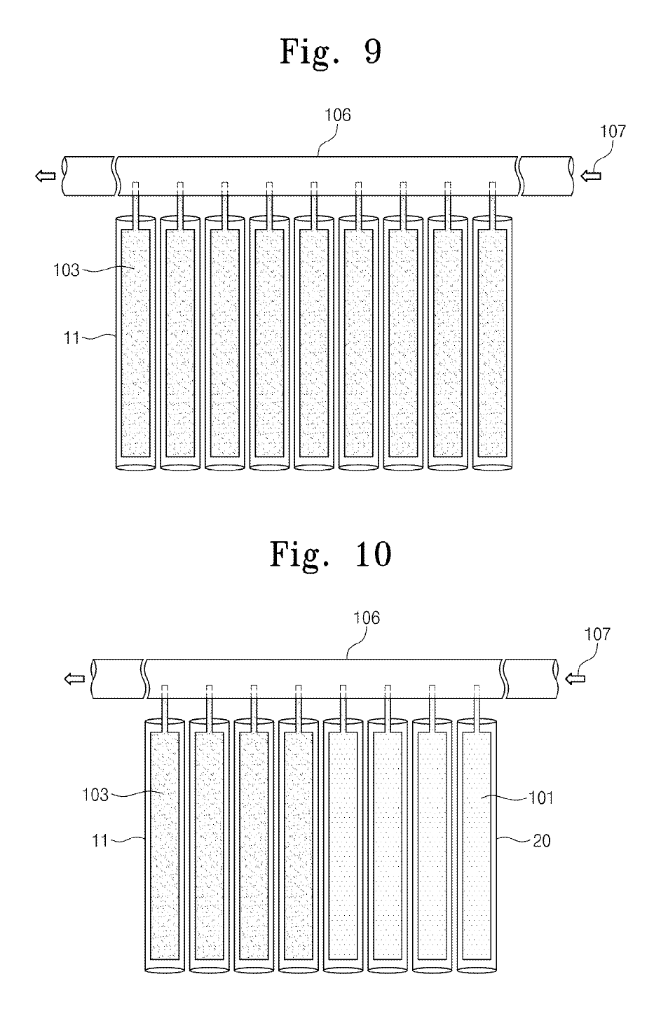

FIG. 8 is a cross-sectional view illustrating a sunlight complex module including a mold having a tetragonal structure, according to another embodiment of the present invention.

Referring to FIG. 8, a sunlight complex module 18 according to the current embodiment includes a mold 104 that may accommodate a heat collector board 101, a heat pipe 102, a photovoltaic conversion part 103, and an adhesion part 105. An inner structure of the mold 104 is similar to that of the sunlight complex module 12 of FIG. 2.

The mold 104 has a tetragonal cross section that is different from the circular cross section of the sunlight complex module 12. Thus, the mold 104 may have a tetragonal column shape.

As illustrated in FIGS. 7 and 8, the sunlight complex modules 17 and 18 may have an oval cross section and a tetragonal cross section, unlike a circular cross section.

Furthermore, the mold 104 of the sunlight complex modules 11, 12, 13, 14, 15, and 16 of FIGS. 1 to 6 may have an oval cross section or a tetragonal cross section as illustrated in FIGS. 7 and 8, or a semi-circular cross section, instead of the circular cross section.

FIG. 9 is a schematic view illustrating an apparatus for using solar energy, which includes an array of sunlight complex modules, according to another embodiment of the present invention.

Referring to FIG. 9, an apparatus for using solar energy according to the current embodiment may include a sunlight complex module 11 as illustrated in FIG. 1. The sunlight complex module 11 include a photovoltaic conversion part 103 disposed above a heat collector board 101. The sunlight complex module 11 is provided in plurality to the apparatus.

The apparatus may further include a passage 106 through which a fluid flows, a heat storage, and a storage battery (a collector).

The photovoltaic conversion part 103 of the sunlight complex modules 11 may transmit electrical energy converted from sunlight, to the collector or the storage battery through a conductive wire. The electrical energy stored in the collector or the storage battery may be used to supply electricity to a building or facility.

The heat collector board 101 of the sunlight complex modules 11 collects heat, and transfers the heat to the heat pipe 102 disposed under the heat collector board 101. The heat pipe 102 is connected to the passage 106 that recovers heat. The heat collected in the heat collector boards 101 is transferred to the fluid (or liquid) flowing through the passage 106, through evaporation and condensation of a fluid within the heat pipe 102. A flow direction 107 of the fluid flowing through the passage 106 is depicted with an arrow. The fluid flowing through the passage 106 may transfer the heat transferred through the heat pipes 102, to the heat storage. As such, thermal energy stored in the heat storage is used as a heat source for heating air and water within a building or facility.

The sunlight complex modules 11 are arrayed in the apparatus. The apparatus may be installed on a large land or the top or outer wall of a building to collect solar energy.

FIG. 10 is a schematic view illustrating an apparatus for using solar energy, a portion of which includes sunlight complex modules, according to another embodiment of the present invention.

Referring to FIG. 10, a portion of an apparatus for using solar energy according to the current embodiment includes sunlight complex modules 11, and the rest thereof includes sunlight modules 20 that include heat collector boards 101 and heat pipes 102. Since the sunlight modules 20 do not include a photovoltaic conversion part 103, the sunlight modules 20 do not generate electrical energy. Thus, the sunlight modules 20 generate only thermal energy.

Accordingly, the apparatus may generate electrical energy and thermal energy through the sunlight complex modules 11 (e.g., four sunlight complex modules) at the left side thereof, and generate thermal energy through the sunlight modules 20 (e.g., four sunlight modules) at the right side thereof. The thermal energy may be transferred to a heat storage through a passage 106 connected to the heat pipes 102.

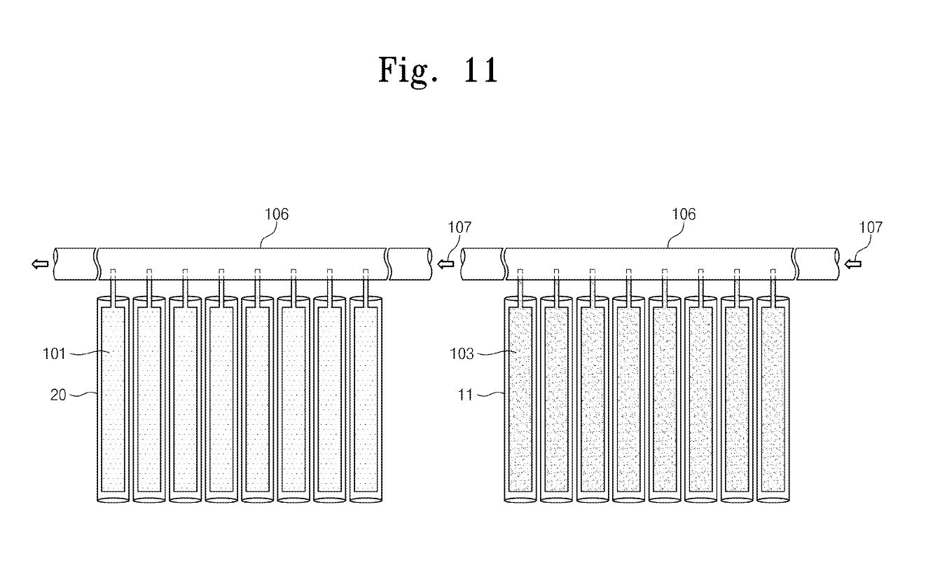

FIG. 11 is a schematic view illustrating an apparatus for using solar energy, a portion of which includes a sunlight complex module set, according to another embodiment of the present invention.

Referring to FIG. 11, an apparatus for using solar energy according to the current embodiment includes a sunlight complex module set and a sunlight module set. The sunlight complex module set includes a plurality of sunlight complex modules 11, the number of which is preset. The sunlight module set includes a plurality of sunlight modules 20, the number of which is preset. That is, a portion of the apparatus may include the sunlight complex module set, and the rest thereof may include the sunlight module set.

Each of the sunlight complex modules 11 constituting the apparatus of FIGS. 9 to 11 may be replaced with one of the sunlight complex modules 12, 13, 14, 15, and 16 of FIGS. 2 to 6.

According to the embodiments of the present invention, a sunlight complex module simultaneously carries out an electricity generating process and a heat collecting process, thereby significantly improving energy usage efficiency. In addition, since the sunlight complex module has an integrated structure, an area required to install the sunlight complex module is significantly smaller than that of a typical sunlight complex module.

In addition, since the sunlight complex module is disposed in a vacuum within a mold, a solar cell is prevented from being exposed to the environment thereof, thereby ensuring the service life and long-term reliability thereof. In addition, a photovoltaic conversion part heated during a photovoltaic conversion operation is cooled by a heat collector part of the sunlight complex module, so that electricity generating efficiency of the photovoltaic conversion part can be ensured.

In addition, since the photovoltaic conversion part is disposed on a heat collector board, a photovoltaic conversion process and a heat collecting process can be simultaneously performed. In addition, sunlight incident to the sunlight complex module is converted into electricity by the photovoltaic conversion part, and a portion of sunlight, which has a wavelength to pass through the photovoltaic conversion part, is used to collect heat, thereby maximizing energy usage efficiency.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A sunlight complex module comprising:
a photovoltaic conversion part that generates electrical energy from sunlight;
a heat collector board attached to a bottom of the photovoltaic conversion part to collect heat from a portion of the sunlight, which has a wavelength to pass through the photovoltaic conversion part;
a heat pipe attached to the heat collector board, and transferring thermal energy collected in the heat collector board, to an outside thereof; and
a mold sealed to maintain a vacuum therein,
wherein the photovoltaic conversion part, the heat collector board, and the heat pipe are accommodated in the mold.

2. The sunlight complex module of claim 1, wherein the heat pipe transfers the thermal energy to the outside thereof through a phase transition between gas and liquid.

3. The sunlight complex module of claim 1, wherein an inner wall of the heat pipe has one of a wick structure and a groove structure.

4. The sunlight complex module of claim 1, wherein the mold has one of a circular cross section, an oval cross section, a tetragonal cross section, and a semi-circular cross section.

5. The sunlight complex module of claim 1, wherein the photovoltaic conversion part comprises at least one of a dye-sensitized solar cell, a copper-indium-selenium (CIS) solar cell, a cadmium-telluride (CdTe) solar cell, and an organic solar cell.

6. The sunlight complex module of claim 1, wherein the photovoltaic conversion part comprises a plurality of photovoltaic conversion devices that are disposed on the heat collector board.

7. The sunlight complex module of claim 1, further comprising an adhesion part disposed between the photovoltaic conversion part and the heat collector board to attach the photovoltaic conversion part to an upper portion of the heat collector board.

8. The sunlight complex module of claim 1, wherein a portion of the heat pipe protruding from the mold is sealed to maintain the vacuum in the mold.

9. An apparatus for using solar energy, comprising:
a plurality of sunlight complex modules;
a passage through which a fluid medium transfers thermal energy transferred from the sunlight complex modules;
a heat storage storing the thermal energy transferred through the passage; and
a collector that stores electrical energy transferred from the sunlight complex modules,
wherein each of the sunlight complex modules comprises:
a photovoltaic conversion part that generates electrical energy from sunlight;
a heat collector board attached to a bottom of the photovoltaic conversion part to collect heat from a portion of the sunlight, which has a wavelength to pass through the photovoltaic conversion part;
a heat pipe attached to the heat collector board, and transferring thermal energy collected in the heat collector board, to an outside thereof; and
a mold sealed to maintain a vacuum therein,
wherein the photovoltaic conversion part, the heat collector board, and the heat pipe are accommodated in the mold.

10. The apparatus of claim 9, wherein the fluid medium of the passage receives thermal energy from the heat pipe.

11. The apparatus of claim 9, further comprising a conductive wire connected to the heat collector board to receive the electrical energy.

12. The apparatus of claim 11, wherein the collector collects the electrical energy through the conductive wire.
